(19) United States
(12) Patent Application Publication
(10) Pub. No.: US 2025/0048604 A1
(43) Pub. Date: Feb. 6, 2025

(54) HEAT SINK FOR COOLING AN ELECTRICAL AND/OR ELECTRONIC ASSEMBLY

(71) Applicant: Robert Bosch GmbH, Stuttgart (DE)

(72) Inventors: Tim Liewer, Gaeufelden (DE); Thomas Maerz, Metzingen (DE); Tobias Hoppe, Kuppenheim (DE)

(21) Appl. No.: 18/716,642

(22) PCT Filed: Nov. 15, 2022
(86) PCT No.: PCT/EP2022/081887

§ 371 Date: Jun. 5, 2024

(30) Foreign Application Priority Data
Dec. 13, 2021 (DE) 10 2021 214 226.5

(51) Int. Cl. H05K 7/20

(52) U.S. Cl. CPC H05K 7/20927; H05K 7/20254

(57) ABSTRACT

For a heat sink (1) for cooling an electrical and/or electronic assembly (4), in particular for electric vehicles or hybrid vehicles,
wherein the heat sink (1) comprises at least one base plate (2) and at least one top plate (3), wherein the base plate (2) is formed as a deep-drawn metal sheet with an indentation (20), wherein the top plate (3) covers the indentation (20) in the base plate (2) so that a cooling duct (5) is formed in the indentation (20) of the base plate (2) between the base plate (2) and the top plate (3), wherein the cooling duct (5) runs from an inlet opening (8) to an outlet opening (9) of the heat sink (1), wherein the inlet opening (8) and the outlet opening (9) are formed in the base plate (2),
it is proposed that an intermediate plate (10) having a first side (11) and a second side (12) facing away from the first side (11) is arranged between the top plate (3) and the base plate (2), wherein the first side (11) of the intermediate plate (10) faces the top plate (3) and the intermediate plate (10) is distanced from the top plate (3) by a gap (7), wherein the inlet opening (8) is formed in a first base region (22) of the base plate (2) and the outlet opening (9) is formed in a second base region (23) of the base plate (2), wherein the first base region (22) is spaced apart from the second side (12) of the intermediate plate (10) by an inlet space (82) and the second base region (23) is spaced apart from the second side (12) of the intermediate plate (10) by an outlet space (92).

### BACKGROUND

The invention relates to a heat sink for cooling an electrical and/or electronic assembly.

Power modules, such as inverter structures or converter structures, are used in hybrid vehicles or electric vehicles. For example, to operate an electric machine, inverters that provide phase currents to the electric machine are used. The power modules can, for example, comprise a carrier substrate with conductor tracks on which, for example, power semiconductors are arranged which, together with the carrier substrate, form an electronic unit. During operation, heat is generated by the electronic unit, which must be dissipated to a heat sink. For this purpose, the electronic unit is thermally connected to the heat sink. It is known to provide heat sinks with cooling ducts in which a cooling fluid can flow to dissipate the heat from the heat sink. So-called turbulence inserts can be provided in the cooling ducts, which ensure better heat dissipation from the heat sink to the cooling fluid flowing through the heat sink. The turbulence inserts generate turbulent flows and increase the cooling surface.

### SUMMARY

According to the invention, a heat sink for an electrical and/or electronic assembly, in particular for electric vehicles or hybrid vehicles, is proposed. The heat sink comprises at least one base plate and at least one top plate, wherein the base plate is formed as a deep-drawn sheet metal with an indentation, wherein the top plate covers the indentation in the base plate, so that a cooling duct is formed in the indentation of the base plate between the base plate and the top plate, wherein the cooling duct extends from an inlet opening to an outlet opening of the heat sink, wherein the inlet opening and the outlet opening are formed in the base plate. According to the invention, an intermediate plate with a first side and a second side facing away from the first side is arranged between the top plate and the base plate, wherein the first side of the intermediate plate faces the top plate and the intermediate plate is spaced from the top plate by a gap, wherein the inlet opening is formed in a first base region of the base plate and the outlet opening is formed in a second base region of the base plate, wherein the first base region is spaced from the second side of the intermediate plate by an inlet space and the second base region is spaced from the second side of the intermediate plate by an outlet space.

Compared to the prior art, the heat sink with the features of the independent claim has a particularly high efficiency with regard to cooling the electrical and/or electronic assembly to be cooled while at the same time having a compact heat sink design. Thanks to the intermediate plate in the heat sink, the inlet opening and the outlet opening of the heat sink can also be advantageously arranged below the intermediate plate in the base plate without affecting the flow of the cooling current below the top plate on which the electrical and/or electronic assembly rests. The arrangement of the inlet opening and/or the outlet opening below the intermediate plate and the surfaces to be cooled means that the top plate of the heat sink can have an advantageously small surface area expansion. This means that the heat sink occupies an advantageously small amount of installation space in the plane of the top plate and the top plate of the heat sink only extends slightly beyond the surface required to support the electrical and/or electronic assembly. The gap between the intermediate plate and the top plate also ensures a uniform flow of the cooling fluid underneath the top plate. As a result, the flow guide in the heat sink ensures a low installation space requirement in the extension plane of the top plate and yet good and uniform cooling of an electrical and/or electronic assembly arranged on the top plate.

The intermediate plate also has the advantage of increasing the rigidity of the entire heat sink. By increasing the rigidity through the intermediate plate, the top plate can have an advantageously low thickness, so that heat from the electrical and/or electronic assembly can be dissipated advantageously well and efficiently to the cooling fluid in the gap between the top plate and the intermediate plate.

Further advantageous embodiments and further embodiments of the invention are made possible by the features indicated in the subclaims.

According to an advantageous exemplary embodiment, it is provided that a separating element is arranged between the inlet space and the outlet space, which distances the intermediate plate from the first base region and the second base region and fluidically separates the inlet space from the outlet space on the second side of the intermediate plate. This separates the inlet space from the outlet space on the second side of the intermediate plate. This means that the inlet space and the outlet space are only fluidically connected to each other via the gap between the first side of the intermediate plate and the top plate. This means that the cooling duct in the heat sink runs exclusively from the inlet opening via the inlet space onwards via the gap in the outlet space and then to the outlet opening of the heat sink. This means that the cooling fluid on the first side of the intermediate plate flows through the gap under the top plate and absorbs heat from the top plate.

According to an advantageous exemplary embodiment, it is provided that the inlet opening and/or the outlet opening in the base plate are covered by the intermediate plate. In this way, the inlet opening and the outlet opening can be arranged below the intermediate plate and can also be arranged below the surface of the top plate to be cooled without affecting the flow of the cooling fluid through the cooling duct on the first side of the intermediate plate. The cooling fluid can therefore be supplied to the heat sink on the second side of the intermediate plate. The cooling fluid is then directed around one edge of the intermediate plate onto the first side of the intermediate plate in the gap. The cooling fluid can then flow along the intermediate plate parallel to the top plate through the gap. This ensures that the top plate is cooled evenly and efficiently by the cooling fluid.

According to an advantageous exemplary embodiment, the heat sink further comprises a turbulence insert arranged in the gap between the top plate and the intermediate plate. The turbulence insert advantageously increases the surface area where the cooling fluid is in contact with the heat sink and swirls the cooling fluid flowing through the gap. This improves the cooling of the top plate by the cooling fluid.

According to an advantageous exemplary embodiment, it is provided that the separating element is formed in one piece with the base plate, in particular is formed as an elevation of the base plate against which the intermediate plate rests. As the base plate is designed as a deep-drawn metal sheet, the separating element can be advantageously designed as an elevation between the first base region and the second base region. Thus, the separating element can be a region of the base plate that rests on the second side of the intermediate plate and, in particular, is also attached, preferably soldered, to the second side of the intermediate plate. The separating element thus separates the inlet space from the outlet space of the cooling duct on the second side of the intermediate plate.

According to an advantageous exemplary embodiment, it is provided that the cooling duct runs from the inlet opening via the inlet space further via the gap to the outlet space and to the outlet opening. In this way, the cooling fluid is guided through the heat sink in a targeted manner and flows through the heat sink between the top plate and intermediate plate in an advantageously uniform and straight line, thus achieving an advantageously good and uniform cooling of the top plate.

According to an advantageous exemplary embodiment, the top plate and/or the intermediate plate are designed to be flat. This means that the top plate and the intermediate plate can be manufactured from sheet metal with ease, for example by simple punching. Additional forming, for example by deep drawing, is not necessary. This means that the heat sink as a whole can be manufactured particularly easily in just a few process steps, as only the base plate is deep-drawn and simple, flat metal sheets can be used as the intermediate plate and top plate.

According to an advantageous exemplary embodiment, it is provided that the inlet space, the outlet space and the gap together form the cooling duct, wherein the inlet space is fluidically connected to the gap around a first edge of the intermediate plate, and the outlet space is fluidically connected to the gap around a second edge of the intermediate plate. The cooling duct can thus run on the first side of the intermediate plate between the first edge and the second edge of the intermediate plate, advantageously in a straight line parallel to the intermediate plate and the top plate. The first edge is preferably facing away from the second edge of the intermediate plate.

According to an advantageous exemplary embodiment, it is provided that a step is formed in the base plate in a side region of the base plate, with the intermediate plate resting on the step of the base plate. By placing the intermediate plate on the step of the base plate, the gap is separated from the inlet space and/or the outlet space of the cooling duct. This means that the gap is only connected to the inlet space in the region of the first edge and/or the outlet space is only connected to the gap in the region of the second edge.

According to an advantageous exemplary embodiment, it is provided that the intermediate plate is spaced from the base regions of the base plate by means of a support element. Such a support element can provide additional stability for the intermediate plate in the heat sink and thus an advantageously high stability of the entire heat sink.

### BRIEF DESCRIPTION OF THE DRAWINGS

Exemplary embodiments of the invention are illustrated in the drawing and explained in greater detail in the following description. Shown are:

FIG. 1 a cross-section through a schematic representation of a first exemplary embodiment of the heat sink,

FIG. 2 a cross-section through the schematic representation of the first exemplary embodiment of the heat sink,

FIG. 3 a further cross-section through the schematic representation of the first exemplary embodiment of the heat sink,

FIG. 4 a cross-section through a schematic representation of a second exemplary embodiment of the heat sink,

FIG. 5 a cross-section of a third exemplary embodiment of the heat sink,

FIG. 6 a cross-section through the third exemplary embodiment of the heat sink,

FIG. 7 a lower view of the third exemplary embodiment of the heat sink.

### DETAILED DESCRIPTION

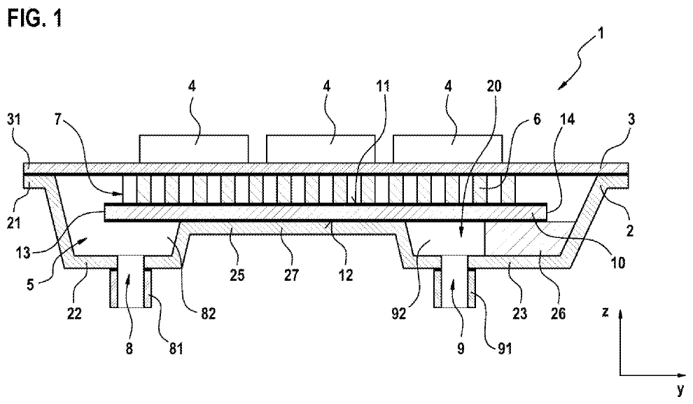

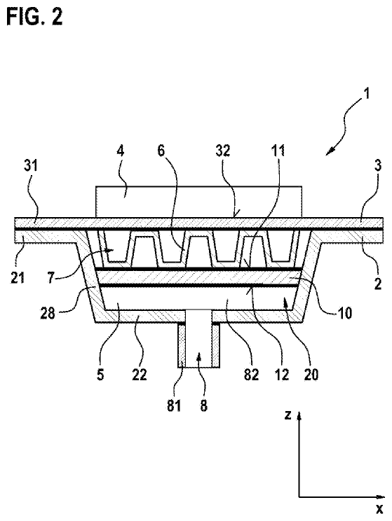

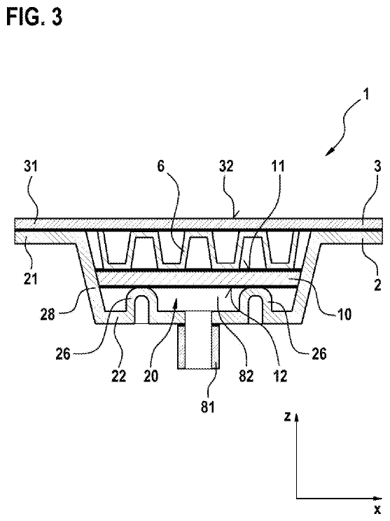

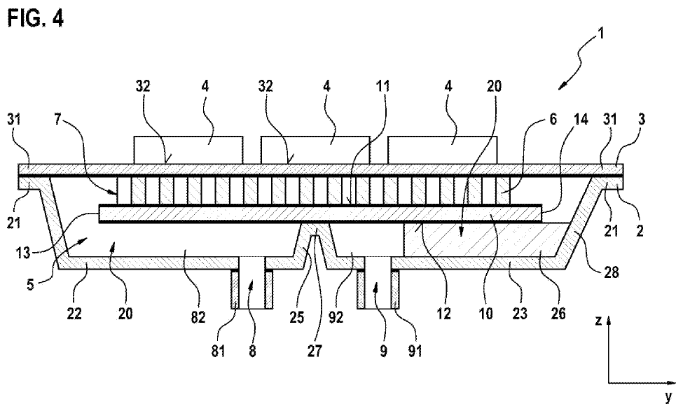

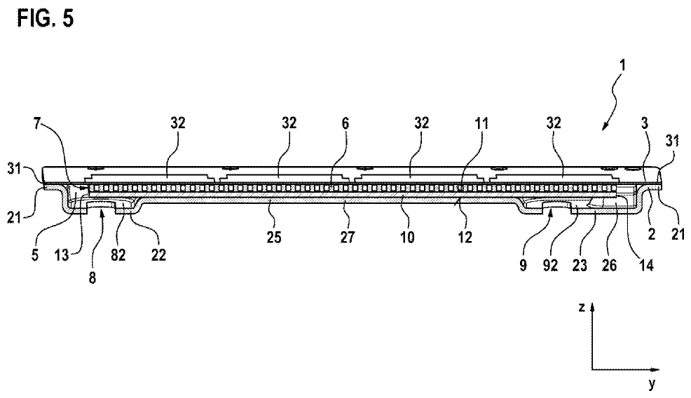

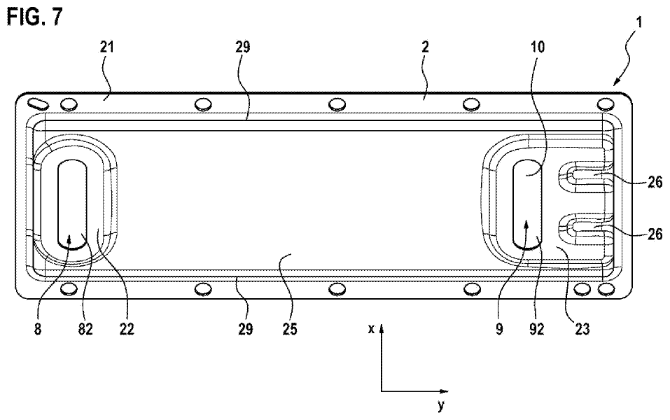

Various exemplary embodiments of the heat sink 1 are shown in the figures. FIGS. 1 through 3 show a schematic representation of a first exemplary embodiment of the heat sink 1. FIG. 4 shows a second exemplary embodiment of the heat sink 1. FIGS. 5 through 7 show a third exemplary embodiment of the heat sink 1. The heat sink 1 can be used, for example, to cool electrical and/or electronic assemblies 4, such as power circuits. These may be, for example, power circuits, such as inverter structures or converter structures, of hybrid vehicles or electric vehicles. For example, the electrical and/or electronic assembly 4 may be configured as a power module and comprise, for example, a carrier substrate having traces on which, for example, power semiconductors are arranged to form an electronic unit together with the carrier substrate. During operation, heat is generated by the electrical and/or electronic assembly 4, which must be dissipated to a heat sink 1. For this purpose, the electrical and/or electronic assembly 4 is arranged on the heat sink 1, for example on a contact surface 32 of a top plate 3 of the heat sink 1. One or more layers can be arranged between the heat sink 1 and the electrical and/or electronic assembly 4 for fastening and thermally connecting the electrical and/or electronic assembly 4 to the heat sink 1. For example, a copper coating can be provided on the contact surface 31 of the top plate 3 facing the electrical and/or electronic assembly 4. As in the exemplary embodiments shown, several, for example three or four, electrical and/or electronic assemblies 4 can be arranged on the heat sink 1, for example next to each other, on the top plate 3 of the heat sink 1. Thus, each of the electrical and/or electronic assemblies 4 is thermally connected to the heat sink 1 and attached to it.

As illustrated in the figures, the heat sink 1 comprises at least one base plate 2, at least one top plate 3 and at least one intermediate plate 10.

The base plate 2 and the top plate 3 form the outer walls of the heat sink 1. The base plate 2 forms the underside of the heat sink 1. The top plate 3 forms the top of the heat sink 1. The base plate 2 and/or the top plate 3 can, for example, be made of a material with high thermal conductivity, such as a metal like aluminum. The base plate 2 and/or the top plate 3 can be sheet metal, for example. The base plate 2 and/or the top plate 3 each have a constant thickness d, for example. The thickness d also refers, for example, to the thickness d of the sheet metal from which the base plate 2 and/or the top plate 3 is made. The base plate 2 and the top plate 3 can have the same thickness d, for example. In the exemplary embodiments, the top plate 3 is thinner than the base plate 2.

An indentation 20 is formed in the base plate 2. The base plate 2 is therefore essentially trough-shaped. The top plate 3 is arranged on the base plate 2 in such a way that the indentation 20 in the base plate 2 is covered by the top plate 3. The base plate 2 and the top plate 3 are arranged next to each other in such a way that a cooling duct 5 is formed between the base plate 2 and the top plate 3 through the indentation 20. The cooling duct 5 runs between the base plate 2 and the top plate 3. The base plate 2 and the top plate 3 form the walls delimiting the cooling duct 5. The base plate 2 is designed as a deep-drawn part. An edge 21 of the base plate 2, which is formed in one plane for example, is connected to an edge 31 of the top plate 3. The edge 21 of the base plate 21 runs all the way around the indentation 20 in the base plate 2. The edge 21 of the base plate 2 rests on the edge 31 of the top plate 3, for example, either directly or with the interposition of an intermediate layer. The edge 21 of the base plate 2 is firmly connected, in particular soldered, to the edge 31 of the top plate 3. The edge 21 of the base plate 2 can be connected, in particular soldered, to the edge 31 of the top plate 3 directly or with the interposition of one or more intermediate layers or intermediate elements. The edge 21 of the base plate 2 is connected to the edge 31 of the top plate 3 using a brazing process, for example. The edge 21 of the base plate 2 is connected, in particular soldered, to the edge 31 of the top plate 3 all the way around the indentation 20.

In the region of the indentation, the base plate 2 is spaced apart from the top plate 3, so that a cavity through which the cooling duct 5 runs is formed between the base plate 2 and the top plate 3. The top plate 3 is flat, for example.

Furthermore, the heat sink 1 comprises an inlet opening 8, via which a cooling fluid can be supplied to the cooling duct 5 in the heat sink 1. Furthermore, the heat sink 1 comprises an outlet opening 9 through which the cooling fluid can flow out of the cooling duct 5 and the heat sink 1. The cooling fluid can be water, for example. The inlet opening 8 and/or the outlet opening 9 can, for example, be formed by openings in the indentation 20 of the base plate 2. The openings are apertures in the base plate 2. As shown in the first and second exemplary embodiments, an inlet nozzle 81 can be arranged or formed at the inlet opening 8. The inlet nozzle 81 can, for example, be a separate component from the base plate 2, for example made of aluminum, which is cylindrical in shape. The inlet nozzle 81 can be attached to the inlet opening 8 by means of a brazed joint. In the same way, an outlet nozzle 91 can be arranged or formed at the outlet opening 9. The outlet nozzle 91 can, for example, be a separate component from the base plate 2, for example made of aluminum, which is cylindrical in shape. The outlet nozzle 91 can be attached to the outlet opening 9, for example by means of a brazed connection. The nozzles 81, 91 can, for example, be joined in the same step as the other parts of the heat sink 1 connected to each other by brazing. A cooling fluid flow of a cooling fluid can flow through the cooling duct 5 from the inlet opening 8 to the outlet opening 9. A cooling fluid can flow into the cooling duct 5 through the inlet opening 8 of the heat sink 1 and flow out of the cooling duct 5 of the heat sink 1 through the outlet opening 9 of the heat sink 1. The cooling duct 5 is designed to feed cooling fluid through the heat sink 1. The cooling duct 5 in the heat sink 1 extends in the heat sink 1 from the inlet opening 8 of the heat sink 1 to the outlet opening 9 of the heat sink 1.

An intermediate plate 10 is arranged between the base plate 2 and the top plate 3. The intermediate plate 10 can be made of a material with high thermal conductivity, for example a metal such as aluminum. The intermediate plate 10 can be designed as a flat metal sheet, for example. The intermediate plate 10 has a first side 11 and a second side 12 facing away from the first side 11. The first side 11 of the intermediate plate 10 faces the top plate 3. The second side 12 of the intermediate plate 10 faces away from the top plate 3. The intermediate plate 10 is flat, for example. For example, the intermediate plate 10 is arranged plane-parallel to the top plate 3. The intermediate plate 10 is spaced from the top plate 3 by a gap 7. The gap 7 forms part of the cooling duct 5, in which the cooling duct runs parallel to the intermediate plate 10 and parallel to the top plate 3 between the top plate 3 and the intermediate plate 10. The intermediate plate 10 extends from a first edge 13 of the intermediate plate 10 to a second edge 14 of the intermediate plate 10. The cooling duct 5 runs in the gap 7 from the first edge 13 of the intermediate plate 10 to the second edge 14 of the intermediate plate 10. The intermediate plate 10 is spaced from base regions 22, 23 of the base plate 2 in the direction of the second side 12 of the intermediate plate 10. The inlet opening 8 of the heat sink 1 is formed in a first base region 22 of the base plate 2. The outlet opening 9 of the heat sink is formed in a second base region 23 of the base plate 2. The first base region 22 and the second base region 23 are spaced apart from the intermediate plate 10 in a direction perpendicular to the intermediate plate 10. The first base region 22 is spaced from the intermediate plate 10 by an inlet space 82. The second base region 23 is spaced from the intermediate plate 10 by an outlet space 92. The first base region 22 and/or the second base region 23 of the base plate 2 are flat, for example. The first base region 22 and/or the second base region 23 of the base plate 2 can extend flat in a common plane. The first base region 22 and/or the second base region 23 of the base plate 2 can be plane-parallel to the intermediate plate 10 and/or to the top plate 3.

The inlet space 82 forms part of the cooling duct 5. The cooling fluid can be supplied to the inlet space 82 via the inlet opening 8. The inlet space 82 is fluidically connected to the gap 7 at the first edge 13 of the intermediate plate 10. The outlet space 92 forms part of the cooling duct 5. The cooling fluid can flow out of the outlet space 92 and thus out of the heat sink 1 via the outlet opening 9. The outlet space 92 is fluidically connected to the gap 7 at the second edge 13 of the intermediate plate 10. The cooling duct 5 of the heat sink 1 thus runs from the inlet opening 8 via the inlet space 82 onwards via the gap 7 to the outlet space 92 and to the outlet opening 9. The inlet space 82, the outlet space 92 and the gap 7 together form the cooling duct 5. The inlet space 82 is fluidically connected to the gap 7 around a first edge 13 of the intermediate plate 10. The outlet space 92 is fluidically connected to the gap 7 around a second edge 14 of the intermediate plate 10. The first edge 13 of the intermediate plate 10 is spaced from the base plate 2 and the top plate 4, so that the inlet space 82 is fluidically connected to the gap 7. The second edge 14 of the intermediate plate 10 is spaced apart from the base plate 2 and the top plate 4, so that the outlet space 92 is fluidically connected to the gap 7. The cooling duct 5 is deflected around the first edge 13 downstream of the gap 7. The cooling duct 5 is deflected upstream of the gap 7 around the second edge 14. This means that the flow of the cooling fluid at the edges 13, 14 does not continue straight ahead, but is diverted to the other side of the intermediate plate 10.

On the second side 12 of the intermediate plate 10, the inlet space 82 and the outlet space 92 are fluidically separated from each other. The inlet space 82 and the outlet space 92 are connected to each other exclusively via the gap 7 on the first side 11 of the intermediate plate 10. The inlet space 82 and the outlet space 92 are fluidically separated from each other by means of a separating element 25 on the second side 12 of the intermediate plate 10. In the exemplary embodiments, the separating element 25 is designed as a region of the base plate 2 that rests against the second side 12 of the intermediate plate 10, in particular is fastened, preferably welded. The separating element 25, which is formed as a region of the base plate 2, is in surface contact with the second side 12 of the intermediate plate 10, for example. The separating element 25 is designed as an elevation 27 between the base regions 22, 23 of the base plate 2. However, the separating element 25 can also be designed, for example, as a separate component from the base plate 2, which rests against the base plate 2 and the intermediate plate 10 and is soldered to them in particular.

Furthermore, one or more support elements 26 may be provided which bear against the second side 12 of the intermediate plate 10, in particular are attached to the second side 12 of the intermediate plate 10, in particular are soldered to the second side 12 of the intermediate plate 10. The support element 26 is arranged between the base plate 2 and the intermediate plate 10. The support element 26 can be a separate component from the intermediate plate 10 and the base plate 2, which is arranged between the intermediate plate 10 and the base plate 2. The support element 26 can also be a region of the base plate 2 which is raised relative to the base regions 22, 23 of the base plate 2 and which bears against the second side 12 of the intermediate plate 10, in particular is attached to the second side 12 of the intermediate plate 10, in particular is soldered to the second side 12 of the intermediate plate 10. The support element 26 can be an elevation of the base plate 2 and can be formed in the base plate 2 during deep drawing of the base plate 2, for example. The support element 26 can be formed in particular in the region of the inlet space 82 and/or the outlet space 92. The support element 26 can, for example, project laterally into the inlet space 82 and/or the outlet space 92.

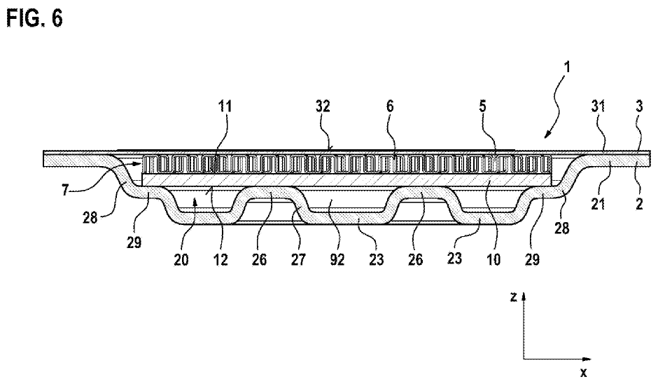

As shown in the third exemplary embodiment, a step 29 can be formed in the base plate 2 at the side region 28 of the base plate 2. The intermediate plate 10 rests, for example, on the step 29 on the base plate 2 and is attached to it, in particular soldered. As shown in FIG. 6, a step 29 can be formed on each of two opposite side regions 28. The second side 12 of the intermediate plate 10 then rests on the opposite edges of the intermediate plate 10 on the steps and, in particular, is also connected to them, in particular soldered to them. The intermediate plate 10 rests on the steps 29 in the same plane as on the separating element 25 and/or the support element 26. The steps 29 can be formed in particular in the region of the inlet space 82 and the outlet space 92.

As shown in the exemplary embodiments, the inlet opening 8 and the outlet opening 9 are covered by the intermediate plate 10. The inlet opening 8 and the outlet opening 9 are thus arranged between the first edge 13 and the second edge 14 of the intermediate plate 10, viewed in a direction perpendicular to the intermediate plate 10. A projection of the inlet opening 8 perpendicular to the intermediate plate 10 lies completely on the intermediate plate 10. A projection of the outlet opening 9 perpendicular to the intermediate plate 10 lies completely on the intermediate plate 10.

Furthermore, the heat sink comprises at least one turbulence insert 6. The turbulence insert 6 is arranged in the gap 7. The turbulence insert 6 is arranged between the top plate 3 and the intermediate plate 10. The turbulence insert 6 can extend from the top plate 3 to the intermediate plate 10 completely through the cooling duct 5. In particular, the turbulence insert 6 is in indirect and/or direct thermally conductive contact with the intermediate plate 10 and with the top plate 3. The turbulence insert 6 is attached to the top plate 3 and/or the intermediate plate 10 using a brazing process, for example. The cooling fluid flows through the turbulence insert 6 parallel to the intermediate plate 10. The turbulence insert 6 has a surface-enlarging, flow-guiding and heat-transferring structure. The turbulence insert 6 is made of a metal with good thermal conductivity, such as aluminum. The turbulence insert can also have a coating, for example. The turbulence insert 6 can be designed as a structured metal sheet, for example. The turbulence insert 6 comprises, for example, a large number of turbulence sections, such as turbulence metal sheets, which are arranged at an angle to the direction of flow of the cooling fluid through the cooling duct 5 in order to turbulently swirl the cooling fluid flowing through the cooling duct 5. This allows the heat to be dissipated particularly effectively. In order to achieve the highest possible cooling efficiency, the turbulence insert 6 fills as much of the flow cross-section of the gap 7 as possible. The turbulence insert 6 extends parallel to the intermediate plate 10 and the top plate 4. The turbulence insert 6 and/or the intermediate plate 10, for example, have essentially the same surface area as the contact surface 32 of the top plate on which the electrical and/or electronic assembly 4 is arranged.

Of course, further exemplary embodiments and mixed forms of the illustrated exemplary embodiments are also possible.

1. A heat sink (1) for cooling an electrical and/or electronic assembly (4),
wherein the heat sink (1) comprises at least one base plate (2) and at least one top plate (3), wherein the base plate (2) is formed as a deep-drawn metal sheet with an indentation (20),
wherein the top plate (3) covers the indentation (20) in the base plate (2) so that a cooling duct (5) is formed in the indentation (20) of the base plate (2) between the base plate (2) and the top plate (3), wherein the cooling duct (5) runs from an inlet opening (8) to an outlet opening (9) of the heat sink (1), wherein the inlet opening (8) and the outlet opening (9) are formed in the base plate (2),
wherein an intermediate plate (10) having a first side (11) and a second side (12) facing away from the first side (11) is arranged between the top plate (3) and the base plate (2),
wherein the first side (11) of the intermediate plate (10) faces the top plate (3) and the intermediate plate (10) is distanced from the top plate (3) by a gap (7),
wherein the inlet opening (8) is formed in a first base region (22) of the base plate (2) and the outlet opening (9) is formed in a second base region (23) of the base plate (2), wherein the first base region (22) is spaced apart from the second side (12) of the intermediate plate (10) by an inlet space (82) and the second base region (23) is spaced apart from the second side (12) of the intermediate plate (10) by an outlet space (92).

2. The heat sink according to claim 1, wherein a separating element (25) is arranged between the inlet space (82) and the outlet space (92), which separates the intermediate plate (10) from the first base region (22) and the second base region (23) and fluidically separates the inlet space (82) on the second side (12) of the intermediate plate (10) from the outlet space (92).

3. The heat sink according to claim 1, wherein the inlet opening (8) and/or the outlet opening (9) in the base plate (2) are covered by the intermediate plate (10).

4. The heat sink according to claim 1, wherein the heat sink (1) further comprises a turbulence insert (6), which is arranged in the gap (7) between the top plate (3) and the intermediate plate (10).

5. The heat sink according to claim 2, wherein the separating element (25) is formed integrally with the base plate (2).

6. The heat sink according to claim 1, wherein the cooling duct (5) extends from the inlet opening (8) via the inlet space (82) further via the gap (7) to the outlet space (92) and to the outlet opening (9).

7. The heat sink according to claim 1, wherein the top plate (3) and/or the intermediate plate (10) are flat.

8. The heat sink according to claim 1, wherein the inlet space (82), the outlet space (92) and the gap (7) together form the cooling duct (5), the inlet space (82) being fluidically connected to the gap (7) around a first edge (13) of the intermediate plate (10), and the outlet space (92) being fluidically connected to the gap (7) around a second edge (14) of the intermediate plate (10).

9. The heat sink according to claim 1, wherein a step (29) is formed in the base plate (2) in a side region (28) of the base plate (2), the intermediate plate (10) resting on the step (29) of the base plate (2).

10. The heat sink according to claim 1, wherein the intermediate plate (10) is spaced apart from the base regions (22, 23) of the base plate (2) by a support element (26).

11. The heat sink according to claim 5, wherein the separating element (25) is formed as an elevation (27) of the base plate (2), against which the intermediate plate (10) bears.

12. The heat sink according to claim 1, wherein the electrical and/or electronic assembly (4) is part of an electric vehicle or a hybrid vehicle.
